(19) United States
(12) Patent Application Publication
(10) Pub. No.: US 2025/0323077 A1
(43) Pub. Date: Oct. 16, 2025

(54) SEMICONDUCTOR CARRIER

(71) Applicant: GUDENG PRECISION INDUSTRIAL CO., LTD., New Taipei City (TW)

(72) Inventors: MING-CHIEN CHIU, New Taipei City (TW); CHIA-HO CHUANG, New Taipei City (TW); KUO-HUA LEE, New Taipei City (TW); JYUN-MING LYU, New Taipei City (TW)

(73) Assignee: GUDENG PRECISION INDUSTRIAL CO., LTD., New Taipei City (TW)

(21) Appl. No.: 18/922,449

(22) Filed: Oct. 22, 2024

Related U.S. Application Data
(60) Provisional application No. 63/633,059, filed on Apr. 12, 2024.

(51) Int. Cl. H01L 21/673

(52) U.S. Cl. CPC H01L 21/67393; H01L 21/67376; H01L 21/67386

(57) ABSTRACT

A semiconductor carrier includes an accommodating chamber formed within a housing, wherein the housing has multiple through holes in communication with the accommodating chamber. A bottom plate is disposed at a bottom of the housing, and includes multiple gas supply portions each corresponding to one of the through holes. Each of the gas supply portions includes an elastic sealing member, which provides airtightness between the gas supply portion and the bottom of the housing. A gas chamber is located on the inside of the elastic sealing member, and the gas chamber and the through holes are in communication with each other to form a gas buffer channel. An installation groove is in communication with the gas chamber, and is configured to be disposed with a gas valve for receiving a gas into the accommodating chamber through the gas buffer channel.

### CROSS-REFERENCE TO RELATED APPLICATION

This non-provisional application claims priority under 35 U.S.C. § 119(e) on U.S. provisional Patent Application No. 63/633,059 filed on Apr. 12, 2024, the entire contents of which are hereby incorporated by reference.

### BACKGROUND OF THE INVENTION

### 1. Field of the Invention

The present disclosure relates to a carrier, and in particular to a semiconductor carrier.

### 2. Description of the Related Art

In order to reduce the humidity in an accommodating chamber within a semiconductor carrier, the accommodating chamber is usually filled with a dry gas. Once the semiconductor carrier is opened, the humidity within the accommodating chamber thereof may rise, hence leading to a requirement of frequently supplementing the dry gas into the accommodating chamber.

To facilitate supplements of the dry gas into the accommodating chamber, a conventional semiconductor carrier is generally provided with multiple through holes, a gas valve is correspondingly disposed in each of the through holes, and multiple diffusion tubes are further provided in the accommodating chamber. Accordingly, filling of the dry gas can be performed from the outside through the multiple gas valves so that the dry gas is uniformly diffused into the accommodating chamber through the multiple diffusion tubes, thereby maintaining a low-humidity environment within the accommodating chamber.

### BRIEF SUMMARY OF THE INVENTION

However, a conventional semiconductor carrier utilizes the multiple diffusion tubes to be in communication with the same buffer gas chamber, and the multiple through holes are also in communication with the buffer gas chamber. Thus, the buffer gas chamber has large volume, and a range of a periphery thereof having to be sealed is accordingly large. Such buffer gas chamber with large volume contains an issue of a slow inflation speed, and a high concentration of volatile organic compounds (VOCs) within the buffer gas chamber is at the same time resulted.

In view of the drawbacks of the prior art above, with dedicated research and development, the applicant provides a semiconductor carrier which has a buffer gas chamber with small volume and is capable of enhancing circulation efficiency of a dry gas as well as reducing the concentration of VOCs.

The directional or similar terms used throughout the present disclosure, for example, “front”, “back/rear”, “left”, “right”, “up/upper/top”, “down/lower/bottom”, “in/inner”, “out/outer” and “side surface”, are primarily provided with reference to the directions of the drawings. These directional or similar terms are intended to assist in describing and better understanding various embodiments of the present disclosure and are not to be construed as limitations to the present disclosure.

The articles “a/an” and “one” used for the elements and components described throughout the present disclosure are merely for the ease of use and to provide common meanings of the scope of the present disclosure, and should be interpreted as “one” or “at least one” in the present disclosure. Moreover, the concept of a singular form also includes cases of plural forms, unless otherwise specified.

Similar terms including “join”, “combine”, “couple” or “assemble” used throughout the present disclosure primarily include forms which can be separated without sabotaging the components or contain inseparable components once connected, and can be selected by a person skilled in the art according to materials or assembly requirements of the components to be connected.

To achieve the above and other objects, the present disclosure provides a semiconductor carrier including: a housing, having an accommodating chamber formed therein, the housing having multiple through holes in communication with the accommodating chamber; and a bottom plate, disposed at a bottom of the housing, the bottom plate including multiple gas supply portions. Each of the gas supply portions corresponds to one of the through holes, and includes: an elastic sealing member, providing airtightness between the gas supply portion and the bottom of the housing; a gas chamber, located on the inside of the elastic sealing member, the gas chamber and the through hole being in communication with each other and forming a gas buffer channel; and an installation groove, in communication with the gas chamber, the installation groove configured to be disposed with a gas valve for receiving a gas into the accommodating chamber through the gas buffer channel.

In the semiconductor carrier above, the gas supply portion can further include an annular inner sidewall and an annular outer wall, and an annular groove is defined between the annular inner sidewall and the annular outer wall. The elastic sealing member is disposed in the annular groove, such that the elastic sealing member is tightly fitted between the annular inner sidewall and the annular outer wall, and the gas chamber is defined within the annular inner sidewall.

In the semiconductor carrier above, the elastic sealing member can protrude from top surfaces of the annular inner sidewall and the annular outer wall, and a top surface of the elastic sealing member can abut against the bottom of the housing to form airtightness.

In the semiconductor carrier above, the annular outer sidewall can be multiple sheets arranged annularly at intervals, thereby defining an elastic buffer margin of the elastic sealing member disposed in the annular groove.

In the semiconductor carrier above, the gas supply portion can further include a spacer. The spacer separates spaces of the gas chamber and the installation groove, and can have multiple openings to communicate the gas chamber with the installation groove.

In the semiconductor carrier above, the spacer can be provided with a filter for first filtering the gas that is then forwarded into the accommodating chamber through the gas buffer channel.

In the semiconductor carrier above, an inner wall of the installation groove can be provided with multiple stop portions at intervals, an outer edge of the gas valve can be provided with multiple engaging portions, and the engaging portions can be correspondingly engaged at the stop portions for the gas valve to be fixed in the installation groove.

In the semiconductor carrier above, each of the stop portions can have a first inclined surface, each of the engaging portions can have a second inclined surface, and the second inclined surface can move relative to the first inclined surface until the engaging portion is correspondingly engaged in the stop portion, or the engaging portion is disengaged from the stop portion.

The semiconductor carrier above can further include multiple diffusion tubes, an inner bottom surface of the accommodating chamber can be disposed with multiple hollow coupling structures, the multiple diffusion tubes can be respectively sleeved and tightly fitted on the multiple hollow coupling structures, and the corresponding diffusion tube, hollow coupling structure and through hole are in communication with each other.

In the semiconductor carrier above, the gas chamber and the installation groove can protrude in a direction from the bottom plate toward the bottom of the housing and are formed integrally.

Accordingly, in the semiconductor carrier of the present disclosure, with each of the gas valves provided with one gas supply portion, the volume of the gas chamber of each of the gas supply portions is reduced and a range of a periphery of the gas chamber having to be sealed is also reduced, hence more easily achieving and maintaining airtightness. Moreover, an inflation speed can be increased owing to the gas chamber with small volume so as to enhance circulation efficiency of a dry gas and reduce the concentration of VOCs released into the buffer gas chamber and released by the material of the bottom plate and/or the housing, thereby improving quality of the dry gas input into the accommodating chamber.

### BRIEF DESCRIPTION OF THE DRAWINGS

FIG. 1 is an exploded perspective schematic diagram according to an embodiment of the disclosure.

FIG. 2 is a partial exploded perspective schematic diagram from another angle of view according to an embodiment of the disclosure.

FIG. 3 is a partial bottom schematic diagram according to an embodiment of the disclosure.

FIG. 4 is a cross-sectional structural schematic diagram taken along the section line A-A in FIG. 3.

FIG. 5 is a partial cross-sectional perspective schematic diagram of a bottom plate according to an embodiment of the disclosure.

FIG. 6 is an exploded perspective schematic diagram of a part of a bottom plate and a gas valve according to an embodiment of the disclosure.

FIG. 7 is a partial cross-sectional perspective schematic diagram of a gas valve joined with a bottom plate according to an embodiment of the disclosure.

FIG. 8 is a schematic diagram of assembly of a gas valve according to an embodiment of the disclosure.

FIG. 9 is a cross-sectional structural schematic diagram taken along the section line B-B in FIG. 3.

### DETAILED DESCRIPTION OF THE INVENTION

To facilitate understanding of the object, characteristics and effects of the present disclosure, embodiments together with the attached drawings for the detailed description of the present disclosure are provided below.

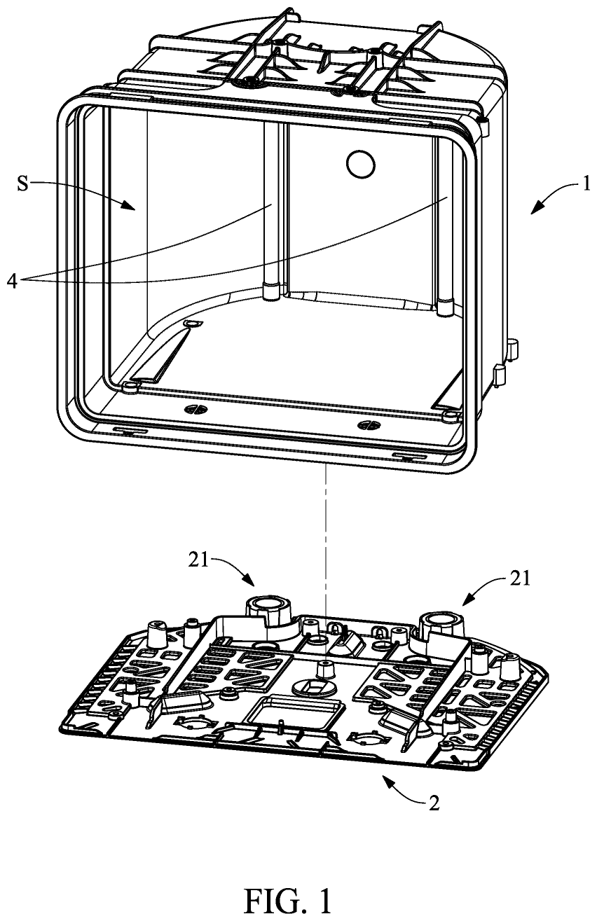

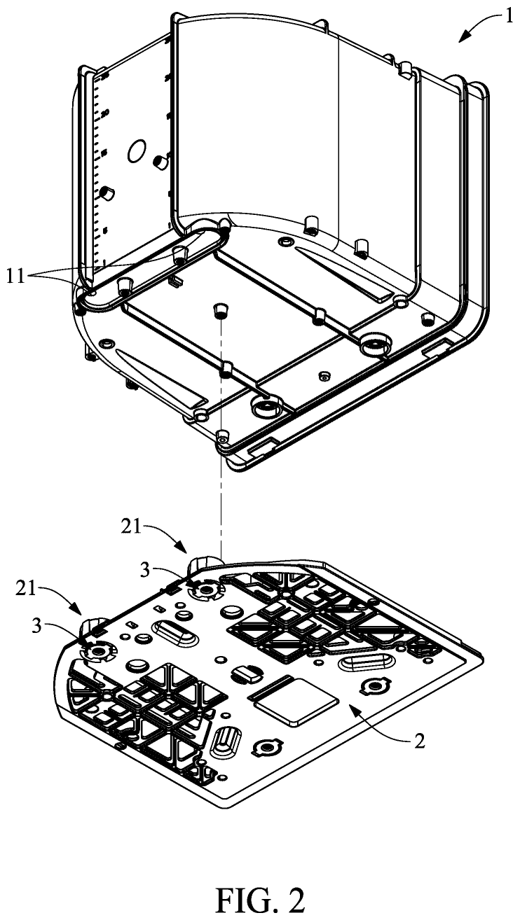

Referring to FIG. 1 and FIG. 2, a semiconductor carrier according to a preferred embodiment of the present disclosure includes a housing 1 and a bottom plate 2. The bottom plate 2 is disposed at a bottom of the housing 1. The housing 1 has an accommodating chamber S formed therein, and includes multiple through holes 11. Each of the through holes 11 passes through inner and outer surfaces of the housing 1 so as to communicate the accommodating chamber S with the outside of the housing 1.

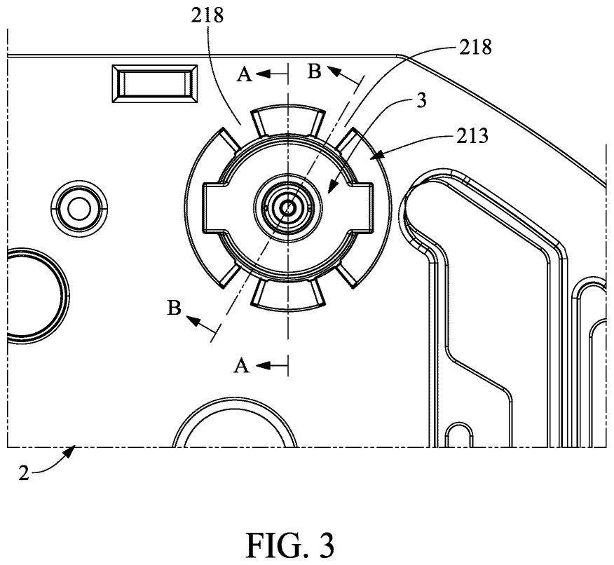

More specifically, referring to FIG. 1 to FIG. 5, the accommodating chamber S of the housing 1 can accommodate a semiconductor workpiece having to be stored with a high level of cleanliness in a low-humidity environment, for example, a piece of wafer, a reticle, a substrate, a carrier board or a related part. A front opening unified pod (FOUP) is exemplified in this embodiment; however, the present disclosure is not limited to this example.

It should be noted that, the bottom plate 2 includes multiple gas supply portions 21 which can transport a gas from the bottom plate 2 to the inside of the housing 1. Each of the gas supply portions 21 corresponds to one of the through holes 11 of the housing 1; that is, the relation between the gas supply portions 21 and the through holes 11 is one-to-one correspondence. Each of the gas supply portions 21 includes an elastic sealing member 211, a gas chamber 212 and an installation groove 213. The elastic sealing member 212 is for forming airtightness between the gas supply portion 21 and the bottom of the housing 1. To achieve airtightness, the gas supply portion 21 further includes an annular inner sidewall 214 and an annular outer sidewall 215, and an annular groove 216 is defined between the annular inner sidewall 214 and the annular outer sidewall 215. An in-groove diameter of the annular groove 216 is slightly less than a horizontal width of the elastic sealing member 211. When the elastic sealing member 211 is disposed in the annular groove 216, the elastic sealing member 211 slightly elastically deforms so as to be tightly fitted between the annular inner sidewall 214 and the annular outer sidewall 215. The elastic sealing member 211 can be, for example but not limited to, an elastic plastic ring, and can be fixed by means of, for example, thermal press, assembling or any other means, in the annular groove 216.

Structural design details of the elastic sealing member 211, the gas chamber 212 and the installation groove 213 are further described below. The gas supply portion 21 further includes a spacer 217 located between the annular inner sidewall 214, the gas chamber 212 and the installation groove 213. The spacer 217 primarily separates spaces of the gas chamber 212 and the installation groove 213. The spacer 217 can appear porous or can have multiple openings so as to communicate the gas chamber 212 with the installation groove 213. Both of the gas chamber 212 and the installation groove 213 are defined within the annular inner sidewall 214, that is, located on the inside of the elastic sealing member 211. The elastic sealing member 211 slightly protrudes from top surfaces of the annular inner sidewall 214 and the annular outer sidewall 215. When the bottom plate 2 is joined with the housing 1, a top surface 2111 of the elastic sealing member 211 can abut against the bottom of the housing 1 to form airtightness, so as to prevent a dry gas transported to the gas chamber 212 from leaking through any joint.

With the matching design of the gas supply portion 21 of the bottom plate 2 and the through hole 11 and the accommodating chamber S of the housing 1, it is learned that a path for an external gas to enter the inside of the accommodating chamber S of the housing 1 is a channel that communicates the installation groove 213, the gas chamber 212, the through hole 11 and the accommodating chamber S. The installation groove 213 is configured to be disposed with a gas valve 3. The gas valve 3 is for receiving a gas for the gas to be transported into the gas chamber 212 through the gas valve 3. Moreover, the gas chamber 212 and the through hole 11 are in communication with each other to form a gas buffer channel W. When the gas valve 3 receives a gas, the gas flows into the accommodating chamber S through the gas buffer channel W. A region of the gas buffer channel W to the through hole 11 can form a buffer gas chamber to provide the gas with an appropriate storage space.

According to the structure above, the semiconductor carrier of this embodiment allows an external inflation apparatus to fill the multiple gas valves 3 with a dry gas. Thus, the dry gas is then input into the multiple gas chambers 212 respectively corresponding to the multiple gas valves 3, so as to further flow into the accommodating chamber S through the through hole 11 corresponding to each of the gas buffer channels W, thereby maintaining a low-humidity environment within the accommodating chamber S.

In the semiconductor carrier of this embodiment, one gas valve 3 is disposed in the installation groove 213 of one gas supply portion 21, such that the volume of the gas chamber 212 of each of the gas supply portions 21 is reduced and a range of a periphery of the gas chamber 212 having to be sealed is also reduced, hence more easily achieving and maintaining airtightness. Moreover, an inflation speed can be increased owing to the gas chamber 212 with small volume so as to enhance circulation efficiency of a dry gas. In addition, the duration of the dry gas residing within the gas chamber 212 is shortened, and so the concentration of VOCs released into the accommodating chamber S and released by the material of the bottom plate 2 and/or the housing 1 is reduced, thereby improving quality of the dry gas input into the accommodating chamber S and mitigating negative influences of VOCs upon a semiconductor workpiece accommodated in the accommodating chamber S.

In the semiconductor carrier of this embodiment, the gas supply portion 21 can be formed by using a simple structure, and the elastic sealing member 211 can be securely disposed at a predetermined position, hence achieving effects of reduced manufacturing costs and enhanced stability for disposing the elastic sealing member 211.

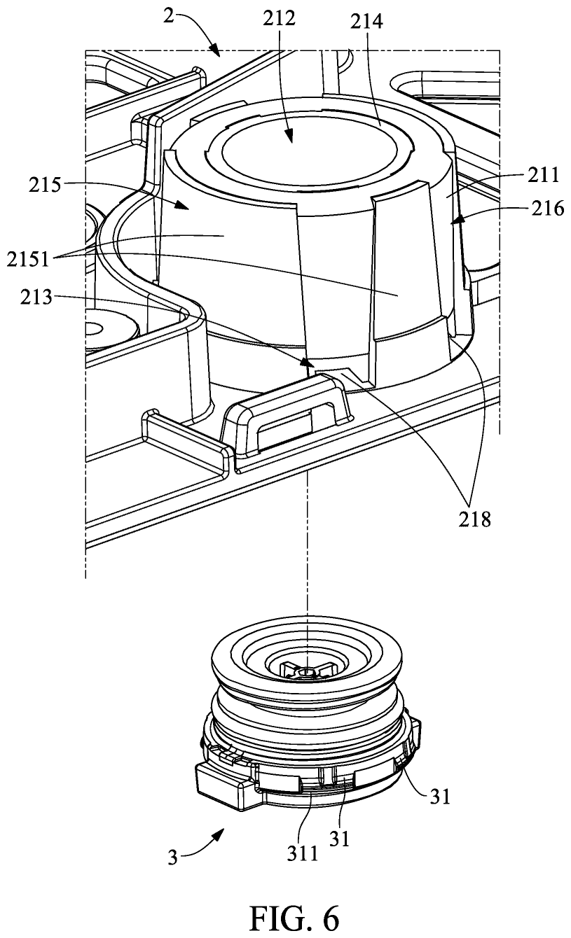

Further referring to FIG. 2 and FIG. 6, in one embodiment of the present disclosure, the annular outer sidewall 215 can be formed as multiple sheets 2151 arranged annularly at intervals. Thus, the multiple sheets 2151 can jointly define an elastic buffer margin of the elastic sealing member 211 disposed in the annular groove 216, and the annular inner sidewall 214 and the annular outer sidewall 215 can be respectively tightly fitted to inner and outer annular walls of the elastic sealing member 211, so as to enhance the stability of the elastic sealing member 211 disposed in the annular groove 216.

In one embodiment of the present disclosure, the bottom plate 2 can be formed to have the corresponding gas chamber 212 and installation groove 213 by a simple structure, and can ensure that a gas port of the gas valve 3 can be aligned with the corresponding gas chamber 212 once the gas valve 3 is installed, hence achieving effects of enhanced ease of manufacturing and assembly.

In one embodiment of the present disclosure, the spacer 217 can be further provided with a filter 2171 for first filtering the gas that is then forwarded into the accommodating chamber S through the gas buffer channel W. The filter 2171 can be disposed on a topmost portion of the installation groove 213, and be pressed by a top end of the gas valve 3. Thus, the level of cleanliness of a filtered gas transported into the accommodating chamber S can be improved.

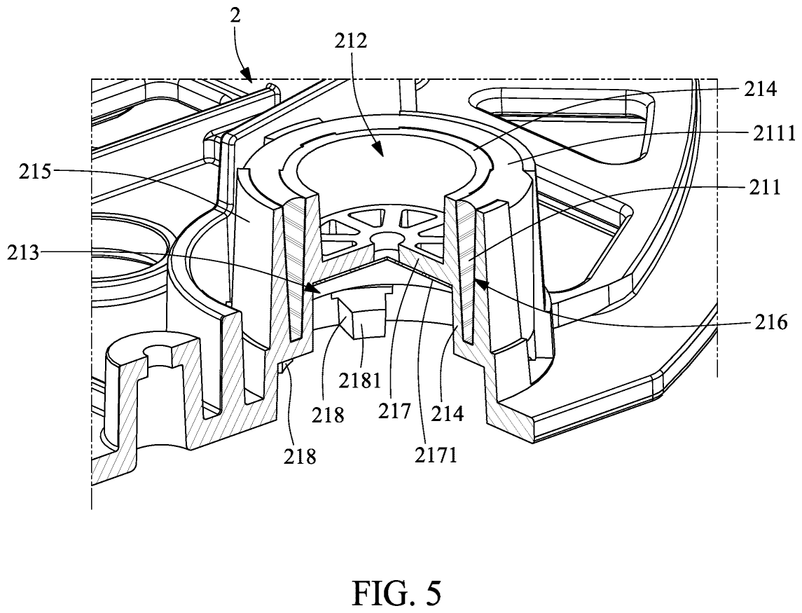

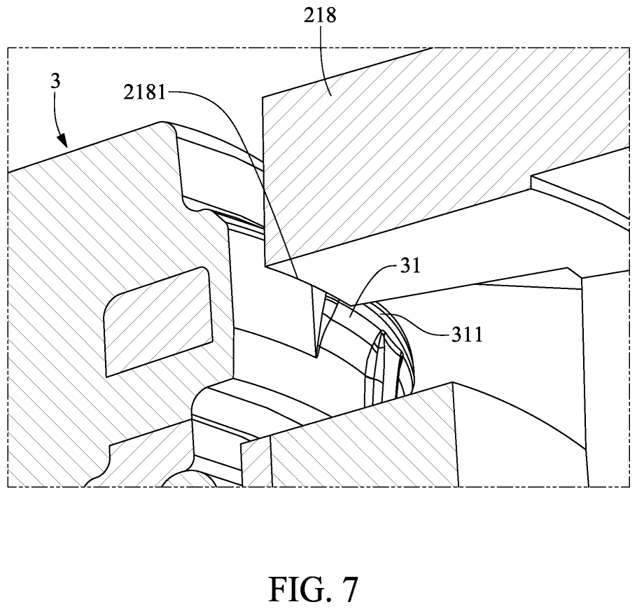

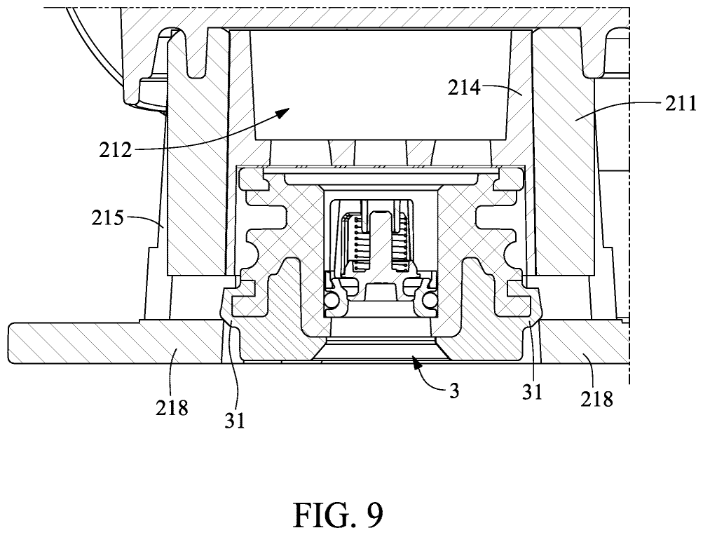

Referring to FIG. 5 to FIG. 9, in one embodiment of the present disclosure, an inner wall of the installation groove 213 can be provided with multiple stop portions 218 at intervals, an outer edge of the gas valve 3 can be provided with multiple engaging portions 31 at intervals, and the engaging portions 31 can be correspondingly engaged at the stop portions 218 for the gas valve 3 to be fixed in the installation groove 213. Thus, with a simple structure of this embodiment, the gas valve 3 can be securely positioned in the installation groove 213, thereby achieving effects of reduced manufacturing costs and enhanced ease of assembly.

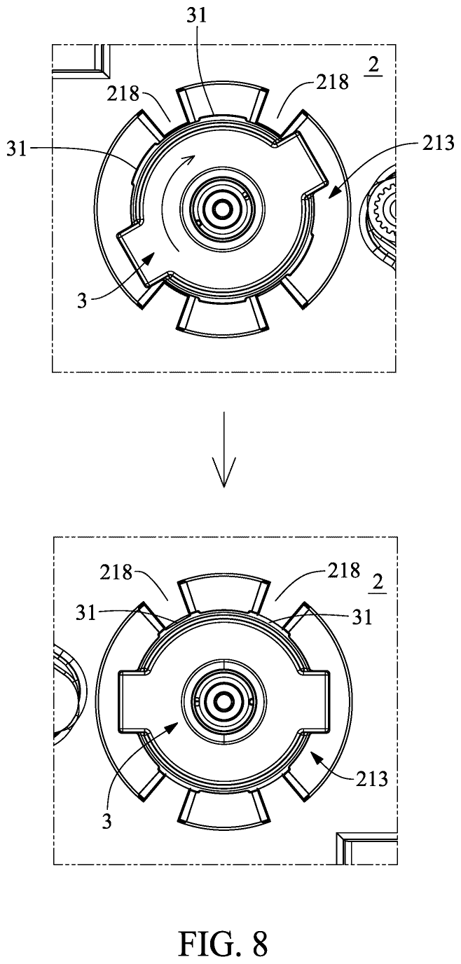

For example but not limited to, in one embodiment of the present disclosure, the stop portion 218 and the engaging portion 31 can be interference fit. For example, the engaging portion 31 of the gas valve 3 can slightly protrude outward and be made of a material having greater elasticity than a body of the gas valve 3. Thus, once the gas valve 3 is placed into the installation groove 213, the engaging portion 31 is made not to face the stop portion 218 (as shown by the upper part in FIG. 8) and is then slightly rotated for the engaging portion 31 to be elastically deformed and forced to a position facing the stop portion 218 (as shown by the lower part of FIG. 8), thereby securely positioning the gas valve 3 in the installation groove 213.

Referring to FIG. 5 to FIG. 7, in order to enhance the smoothness of operations for assembling and removing the gas valve 3, each of the stop portions 218 can have a first inclined surface 2181, and each of the engaging portions 31 can have a second inclined surface 311. The second inclined surface 311 outwardly protrudes from the body of the gas valve 3 in an inclined manner. When the gas valve 3 starts rotating such that the second inclined surface 311 abuts against the first inclined surface 2181 of the stop portion 218, the second inclined surface 311 moves and comes into contact relative to the first inclined surface 2181 until the engaging portion 31 is correspondingly engaged in the stop portion 218, thereby enhancing the smoothness of assembly and reducing friction by means of sliding along the inclined surfaces. Similarly, to remove the gas valve 3, the gas valve 3 is rotated in a reverse direction such that the second inclined surface 311 moves and separates relative to the first inclined surface 2181 until the engaging portion 31 separates and disengages from the stop portion 218, hence removing the gas valve 3 from the gas supply portion 21.

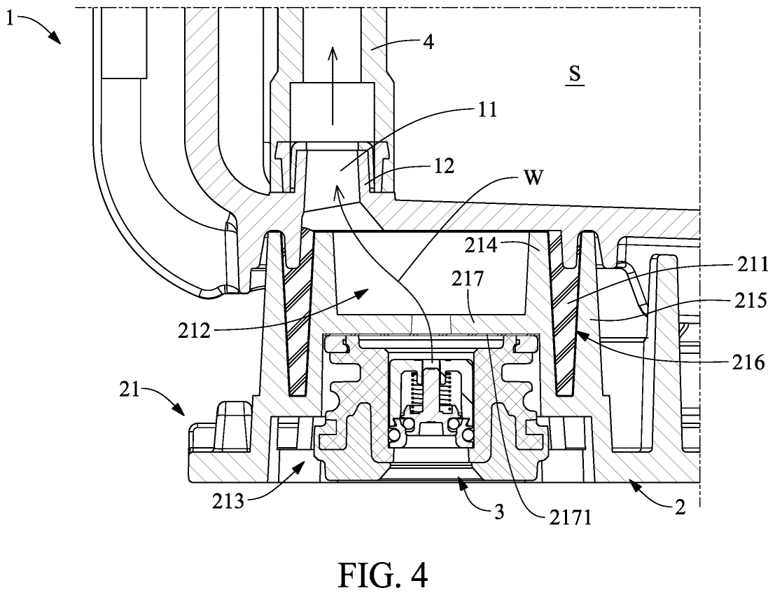

Referring to FIG. 1 and FIG. 4, in one embodiment of the present disclosure, the semiconductor carrier can further include multiple diffusion tubes 4 located within the accommodating chamber S. Each of the diffusion tubes 4 corresponds to and is in communication with one through hole 11. The gas valve 3 is for receiving a gas into the accommodating chamber S through the gas buffer channel W, the through hole 11 and the diffusion tube 4, wherein the gas can be uniformly diffused into the accommodating chamber S through the diffusion tube 4.

An inner bottom surface of the accommodating chamber S can be disposed with multiple hollow coupling structures 12, and each of the hollow coupling structures 12 corresponds in position to each of the diffusion tubes 4. The diffusion tube 4 can be sleeved and tightly fitted on the hollow coupling structure 12 to form airtightness so that the gas does not leak to the outside from any joint, and the ease and accuracy of assembly of the diffusion tube 4 can be enhanced at the same time.

In one embodiment of the present disclosure, the gas chamber 212 and the installation groove 213 can protrude in a direction from the bottom plate 2 toward the bottom of the housing 1 and be formed integrally. Multiple independent buffer gas chambers can be formed. By fixing the gas valve 3 under the bottom plate 2 by the stop portion 218 of the bottom plate 2, sufficient airtightness is increased to quickly guide the gas into the buffer gas chamber, that is, the gas buffer channel W. The gas filtered by the filter 2171 is passed through the diffusion tube 4 and then is guided into the accommodating chamber S within the housing 1. Moreover, the same through hole 11 can be disposed in a direction of an opening of the housing, and the gas supply portion 21 or the gas valve 3 is arranged at the bottom plate at a position corresponding to the through hole 11 for gas leakage, hence effectively discharging excessive VOCs from the accommodating chamber S to the outside of the housing 1 and mitigating influences of the VOCs. In this embodiment, the multiple gas supply portions 21 can be directly formed when the bottom plate 2 is formed so as to readily manufacture the bottom plate 2 and save the time needed for assembly of the multiple gas supply portions 21, and it is also ensured that the multiple gas supply portions 21 can be accurately disposed at predetermined positions on the bottom plate 2. Thus, when the bottom plate 2 is joined with the housing 1, the multiple gas supply portions 21 can also be accurately aligned with the corresponding through holes 11. The bottom plate 2 is a low-moisture absorbing material or a non-low-moisture absorbing material, both of which have a conduction function.

Table-1 shows experimental data of the humidity, concentration of VOCs and toluene measured in time periods of 0 hour and 1 hour for interiors of a conventional semiconductor carrier and a semiconductor carrier of the present disclosure, respectively. The conventional semiconductor carrier is in an implementation form of multiple diffusion tubes sharing one same buffer gas chamber, and the semiconductor carrier of the present disclosure is in an implementation form of each diffusion tube corresponding to an independent buffer gas chamber.

TABLE 1

| | | Concentration | |
|---|---|---|---|
| | Humidity | of VOCs | Toluene |
| Conventional semiconductor | 0.02 | 452.65 | 0.05 |
| carrier - 0 hour | | | |
| Conventional semiconductor | 0.89 | 322.02 | 0.12 |
| carrier - 1 hour | | | |
| Semiconductor carrier of | 0.12 | 328.06 | 0.04 |
| present disclosure - 0 hour | | | |
| Semiconductor carrier of | 0.52 | 315.66 | 0.03 |
| present disclosure - 1 hour | | | |

It is seen from the experimental data in Table-1 that, in terms of humidity, although the humidity in both the conventional semiconductor carrier and the semiconductor carrier of the present disclosure exhibits an increasing trend, the increasing trend of the semiconductor carrier of the present disclosure is significantly moderate than the increasing trend of the conventional semiconductor carrier. Therefore, the semiconductor carrier of the present disclosure has better performance for suppressing an increase in humidity than the conventional semiconductor carrier. In terms of the concentration of VOCs, although the concentration of VOCs in both the conventional semiconductor carrier and the semiconductor carrier of the present disclosure exhibits a decreasing trend, the semiconductor carrier of the present disclosure has a higher inflation speed because of the small volume of the gas chambers and the concentration of VOCs released from the material can be reduced. Therefore, the concentrations of VOCs in time periods of 0 hour and 1 hour are both lower than those of the conventional semiconductor carrier. In terms of toluene, the conventional semiconductor carrier exhibits an increasing trend, whereas the semiconductor carrier of the present disclosure exhibits a decreasing trend. In conclusion, the data showing low humidity, low concentration of VOCs and low toluene of the semiconductor carrier of the present disclosure are all better than those of the conventional semiconductor carrier.

The present disclosure is described by way of the preferred embodiments above. A person skilled in the art should understand that, these embodiments are merely for illustrating the present disclosure and are not to be construed as limitations to the scope of the present disclosure. It should be noted that all equivalent changes, replacements and substitutions made to the embodiments are encompassed within the scope of the present disclosure. Therefore, the legal protection for the present disclosure should be defined by the appended claims and the scope of the claims should be in accordance with the broadest interpretation, so as to encompass all of the modifications, similar arrangements and processes.

What is claimed is:

1. A semiconductor carrier, comprising:
a housing, having an accommodating chamber formed therein, the housing having a plurality of through holes in communication with the accommodating chamber; and
a bottom plate, disposed at a bottom of the housing, the bottom plate comprising a plurality of gas supply portions, each of the gas supply portions corresponding to one of the through holes and comprising:
an elastic sealing member, providing airtightness between the gas supply portion and the bottom of the housing;
a gas chamber, located on the inside of the elastic sealing member, the gas chamber and the through hole being in communication with each other and forming a gas buffer channel; and
an installation groove, in communication with the gas chamber, the installation groove configured to be disposed with a gas valve for receiving a gas into the accommodating chamber through the gas buffer channel.

2. The semiconductor carrier according to claim 1, wherein the gas supply portion further comprises an annular inner sidewall and an annular outer wall, and an annular groove is defined between the annular inner sidewall and the annular outer wall, the elastic sealing member is disposed in the annular groove such that the elastic sealing member is tightly fitted between the annular inner sidewall and the annular outer wall, and the gas chamber is defined within the annular inner sidewall.

3. The semiconductor carrier according to claim 2, wherein the elastic sealing member protrudes from top surfaces of the annular inner sidewall and the annular outer wall, and a top surface of the elastic sealing member abuts against the bottom of the housing to form airtightness.

4. The semiconductor carrier according to claim 2, wherein the annular outer sidewall is a plurality of sheets arranged annularly at intervals, hence defining an elastic buffer margin of the elastic sealing member disposed in the annular groove.

5. The semiconductor carrier according to claim 1, wherein the gas supply portion further comprises a spacer, and the spacer separates spaces of the gas chamber and the installation groove and has a plurality of openings to communicate the gas chamber with the installation groove.

6. The semiconductor carrier according to claim 5, wherein the spacer is provided with a filter for first filtering the gas that is then forwarded to the accommodating chamber through the gas buffer channel.

7. The semiconductor carrier according to claim 1, wherein an inner wall of the installation groove is provided with a plurality of stop portions at intervals, an outer edge of the gas valve is provided with a plurality of engaging portions at intervals, and the engaging portions are correspondingly engaged at the stop portions for the gas valve to be fixed in the installation groove.

8. The semiconductor carrier according to claim 7, wherein each of the stop portions has a first inclined surface, each of the engaging portions has a second inclined surface, and the second inclined surface moves relative to the first inclined surface until the engaging portion is correspondingly engaged in the stop portion, or the engaging portion is disengaged from the stop portion.

9. The semiconductor carrier according to claim 1, further comprising a plurality of diffusion tubes, wherein an inner bottom surface of the accommodating chamber is disposed with a plurality of hollow coupling structures, the plurality of diffusion tubes are respectively sleeved and tightly fitted on the plurality of hollow coupling structures, and the corresponding diffusion tube, hollow coupling structure and through hole are in communication with each other.

10. The semiconductor carrier according to claim 1, wherein the gas chamber and the installation groove protrude in a direction from the bottom plate toward the bottom of the housing and are formed integrally.
